(19) United States
(12) Patent Application Publication
(10) Pub. No.: US 2023/0317729 A1
(43) Pub. Date: Oct. 5, 2023

(54) VERTICAL BIT DATA PATHS FOR INTEGRATED CIRCUITS

(71) Applicant: Intel Corporation, Santa Clara, CA (US)

(72) Inventors: Dmitri Evgenievich Nikonov, Beaverton, OR (US); Chia-Ching Lin, Portland, OR (US); Hai Li, Portland, OR (US); Ian Alexander Young, Olympia, WA (US); Julien Sebot, Portland, OR (US); Punyashloka Debashis, Hillsboro, OR (US)

(73) Assignee: Intel Corporation, Santa Clara, CA (US)

(21) Appl. No.: 17/710,584

(22) Filed: Mar. 31, 2022

(51) Int. Cl. H01L 27/118; H01L 29/78; H01L 29/66

(52) U.S. Cl. CPC H01L 27/11803; H01L 29/78391; H01L 29/66984

(57) ABSTRACT

In one embodiment, an integrated circuit apparatus includes a plurality of metallization layers, each metallization layer comprising voltage supply lines and signal lines. The apparatus also includes logic circuits formed between respective pairs of metallization layers, with each logic circuit comprising non-CMOS logic devices to perform an operation on a respective bit of an input set of bits. The non-CMOS logic devices may include one or more of ferroelectric field-effect transistor (FeFET) devices or spintronic logic devices (e.g., magnetoelectric spin orbit (MESO) devices or ferroelectric spin orbit logic (FSOL) devices), and each logic circuit may be formed on a different vertical plane within the apparatus.

### BACKGROUND

In current integrated circuit designs, bits of a data path are positioned in-plane with one another, i.e., in the horizontal plane of the integrated circuit chip. This requires large surface areas for the formation of these circuits, and this area only grows as data path throughput demands increase.

### BRIEF DESCRIPTION OF THE DRAWINGS

FIGS. 1A-1B illustrate an example in-plane data path architecture for logic circuits of an integrated circuit chip.

FIGS. 2A-2B illustrate an example vertical data path architecture for logic circuits of an integrated circuit chip in accordance with embodiments of the present disclosure.

FIG. 3 illustrates an example logic circuit formed between metallization layers in accordance with embodiments of the present disclosure.

FIGS. 4A-4B illustrate example wiring arrangements for voltage supply and signal lines in integrated circuit chips implemented with CMOS devices and with alternative types of transistor devices, respectively.

FIG. 5 illustrates an example n-channel FeFET that may be implemented in vertically stacked logic circuits in accordance with embodiments of the present disclosure.

FIG. 6 illustrates an integrated circuit structure including a set of example magnetoelectric spin orbit (MESO) logic devices connected to one another in a cascaded fashion in accordance with embodiments of the present disclosure.

FIG. 7 illustrates an integrated circuit structure including an example ferroelectric spin orbit logic (FSOL) device in accordance with embodiments of the present disclosure.

FIG. 8 illustrates a perspective view of a layout of cascaded ferroelectric spin orbit logic (FSOL) circuit including two cascaded FSOL inverters in accordance with embodiments of the present disclosure.

FIG. 9 illustrates another example integrated circuit structure with two FSOL devices connected to one another in a cascaded fashion in accordance with embodiments of the present disclosure.

FIG. 10 is a top view of a wafer and dies that may be included in a microelectronic assembly, in accordance with any of the embodiments disclosed herein.

FIG. 11 is a cross-sectional side view of an integrated circuit device that may be included in a microelectronic assembly, in accordance with any of the embodiments disclosed herein.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

As the demand for computing grows, datacenters become limited by the availability of energy. That necessitates more dramatic increase in energy efficiency (TOPS/W, or Terra-operations per second per Watt). One of the most promising directions towards energy efficiency are low-voltage devices. However, low voltage devices tend to be slower and therefore more circuits are typically needed to perform a given throughput. More circuits result in a larger chip area, which can make them more expensive.

In current integrated circuit designs, bits of a data path are positioned in-plane with one another, i.e., in the horizontal plane of the integrated circuit chip. This requires large surface areas for the formation of these circuits, and this area only grows as data path throughput demands increase. The use of traditional complementary metal oxide semiconductor (CMOS) transistors for the integrated circuit design has prevented the bits from being placed in the vertical plane of the chip, since their operation dissipates relatively large amounts of heat. Thus, forming the CMOS transistor bit circuits between metallization layers of the chip is unfeasible as there is no good heat conduction for them.

However, aspects of the present disclosure may utilize alternative transistor types such as, for example, ferroelectric field-effect transistor (FeFET) devices, spintronic magnetoelectric spin orbit (MESO) devices (e.g., in majority gate configurations), tunnel FETs, or spin wave devices, in a vertical data path of an integrated circuit chip as such devices can be formed between the metallization layers of the integrated circuit chip without the same issues that CMOS devices present. That is, the circuits corresponding to different bits of a data path may be placed vertically relative to each other rather than horizontal as in traditional designs. The vertical stacking may be made possible via the great alleviation of the problem of heat removal presented by traditional CMOS devices. For instance, the power consumption of FeFET- and/or MESO-based circuits can be up to 40× smaller than that of a CMOS-based circuit, with a factor of approximately 10× coming from the lower energy of operation of the devices themselves and a factor of approximately 4× coming from their slower operation.

While these devices may be slower in operation than traditional CMOS devices, and thus require more circuits for the same computing throughput, their use might still result in a decrease of chip area used for an integrated circuit design due to the vertical bit stacking. Moreover, the vertical stacking may require shorter vertical interconnects than horizontal circuits, leading to shorter delays and additionally lower energy consumption in the devices. Furthermore, vertical stacking ability provided by these devices may allow or more freedom in the design of three-dimensional integrated circuits, as the bits can be connected along vertical stacks and/or along the metallization plane.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In addition, as used herein “vertical” refers to the “z” direction, while “horizontal” refers to the “x” direction or the “y” direction, which directions are shown by way of the coordinate systems provided in certain figures.

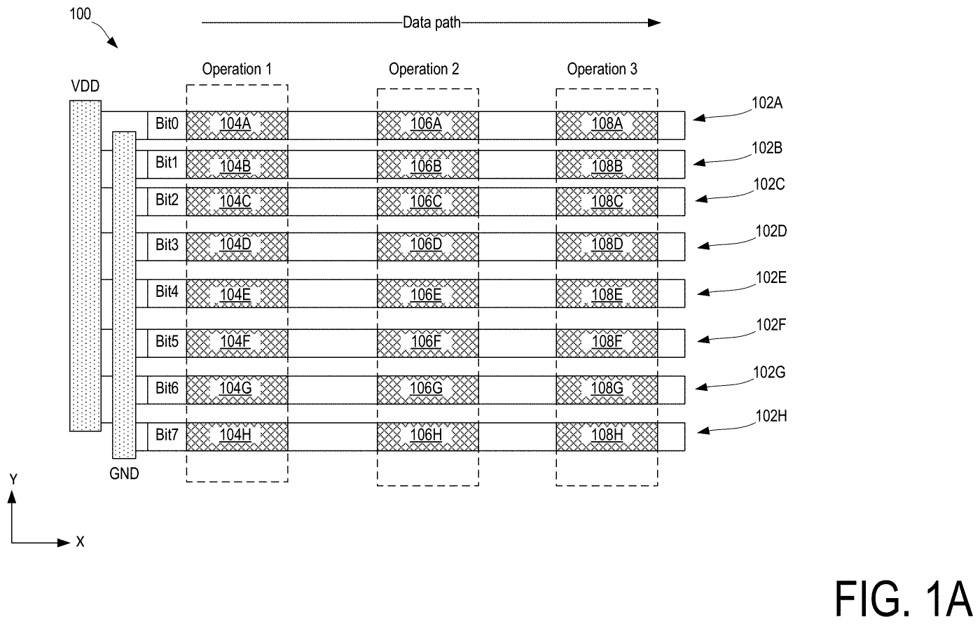

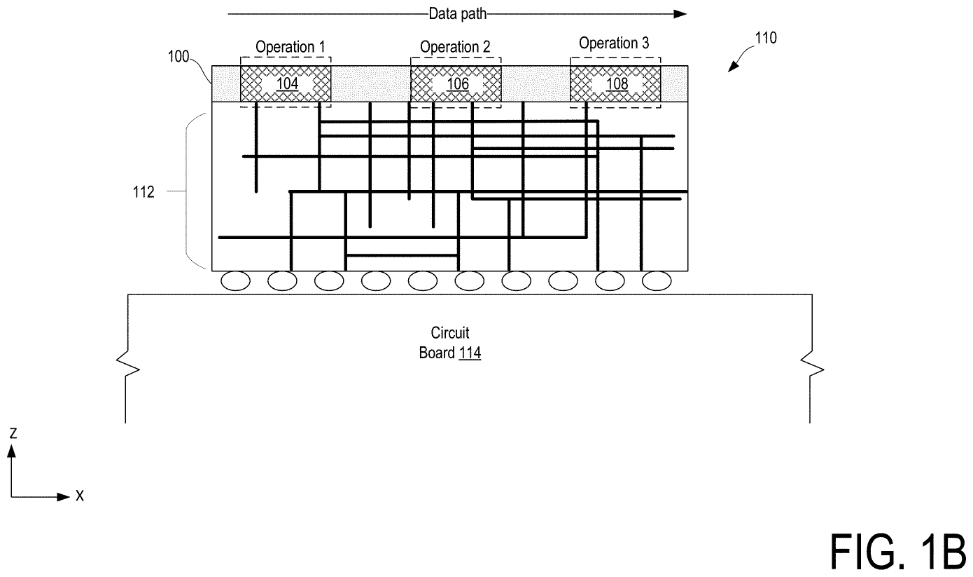

FIGS. 1A-1B illustrate an example in-plane data path architecture 100 for logic circuits of an integrated circuit chip. The in-plane data path architecture 100 may represent a current state of the art for logic circuits implemented with CMOS devices. As shown in FIG. 1B, the in-plane data path architecture 100 sits on top of a chip 110 (relative to the vertical z direction), with multiple metallization layers 112 (e.g., between 10-15, such as 12 layers with 4 fine pitched and 8 courser pitched layers) beneath the data path architecture 100, which may include traces that interconnect different portions of the logic in the data path architecture 100. The chip 110 may attach to a circuit board 114 as shown in FIG. 1B. The circuit board 114 may be a printed circuit board (PCB) including multiple metal (or interconnect) layers separated from one another by layers of dielectric material and interconnected by electrically conductive vias. The individual metal layers may comprise conductive traces. Any one or more of the metal layers may be formed in a desired circuit pattern to route electrical signals (optionally in conjunction with other metal layers) between the components coupled to the circuit board 114, e.g., between the chip 110 and other integrated circuits, power supplies, voltage regulators, memory devices. In some embodiments, the circuit board 114 may be implemented as a package substrate to which the chip 110 attaches. The package substrate may include circuits or wiring that are configured to couple the chip 110 to another circuit board, such as a motherboard. In other embodiments, the circuit board 114 may be implemented as a main board, such as a motherboard, wherein the chip 110 attaches directly to the main board.

The in-plane data path architecture 100 includes a number of logic circuits that implement a number of operations on bits of data. For instance, as shown in FIG. 1A, the in-plane data path architecture 100 is implemented with a data path that includes a first operation (Operation 1) implemented by logic circuits 104, a second operation (Operation 2) implemented by logic circuits 106 and performed on an output of the first operation, and a third operation (Operation 3) implemented by logic circuits 108 and performed on an output of the second operation. The operations may be any suitable operations to be performed on the data, e.g., a flop wordslice operation, a multiplex wordslice operation, a add wordslice operation, etc.

The logic circuits are separated in such a way that each operation is performed on each bitslice 102. For instance, the logic circuits 104A perform the first operation on the first bitslice 102A of input data (Bit0), the logic circuits 104B perform the first operation on the second bitslice 102B of input data (Bit1), the logic circuits 104C perform the first operation on the third bitslice 102C of input data (Bit2), the logic circuits 104D perform the first operation on the fourth bitslice 102D of input data (Bit3), the logic circuits 104E perform the first operation on the fifth bitslice 102E of input data (Bit4), the logic circuits 104F perform the first operation on the sixth bitslice 102F of input data (Bit5), the logic circuits 104G perform the first operation on the seventh bitslice 102G of input data (Bit6), and the logic circuits 104H perform the first operation on the eighth bitslice 102H of input data (Bit7). The second and third operations include separated logic circuits 106, 108, respectively that each perform their operations on the bitslices 102 in a similar manner.

For certain reasons, e.g., heat dissipation of the CMOS devices that implement the logic circuits 104, 106, 108, the logic circuits 104, 106, 108 are all implemented in the top horizontal (x-y) plane of the chip. That is, the bit slices 102 must be implemented in the x-y plane, and as discussed above, this causes the area of the chip 110 in the x-y plane to be quite large especially with more complex circuits. However, by utilizing other transistor types for the logic circuits of the integrated circuit, e.g., FeFET devices, spintronic magnetoelectric spin orbit (MESO) devices, tunnel FETs, or spin wave devices, the logic circuits may be placed in the vertical (z) plane of the integrated circuit chip 110, since these types of devices can be formed between the metallization layers of the integrated circuit chip.

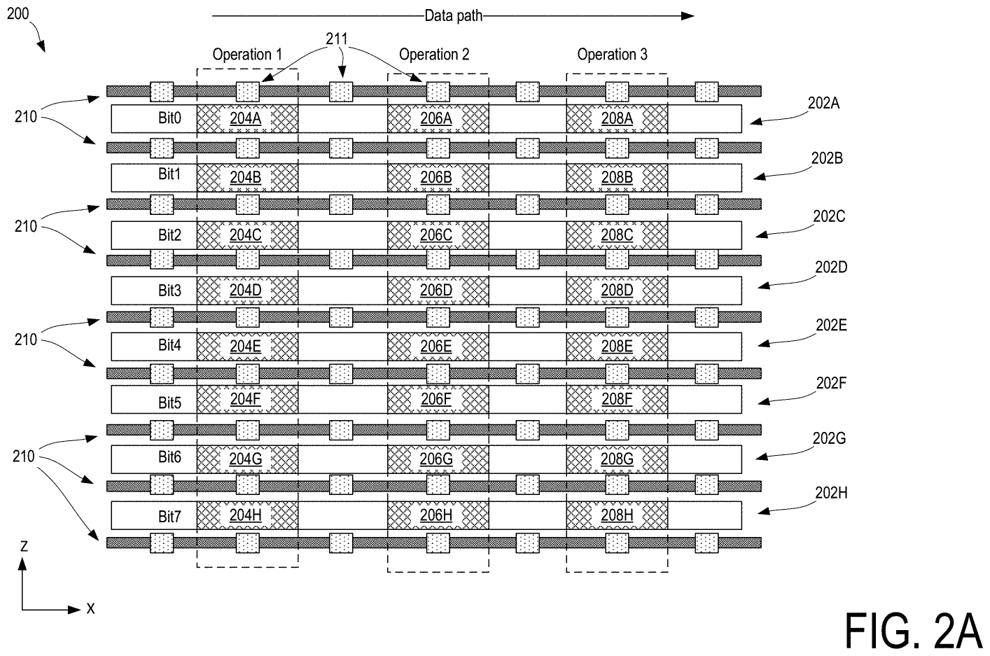

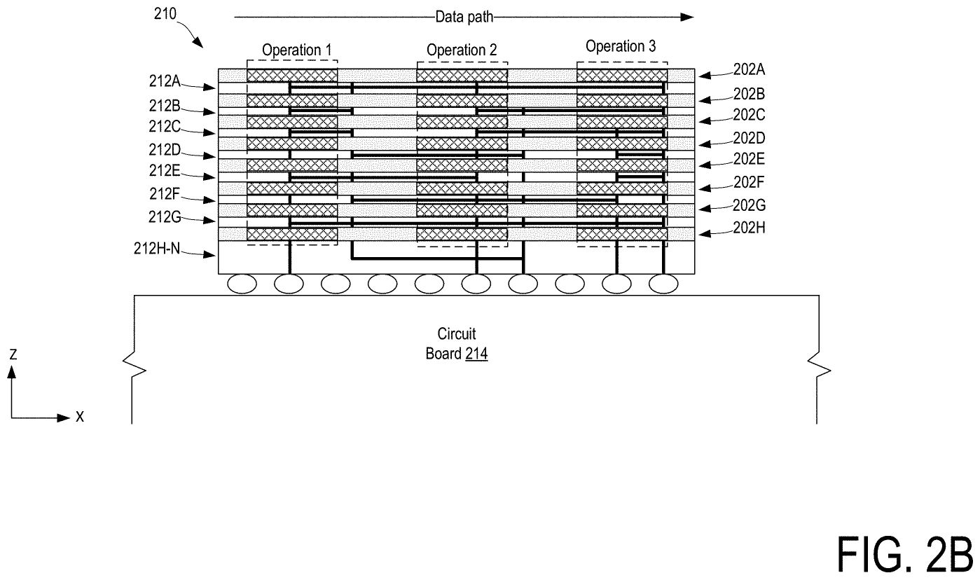

FIGS. 2A-2B illustrate an example vertical data path architecture 200 for logic circuits of an integrated circuit chip in accordance with embodiments of the present disclosure. In the examples shown, the architecture 200 includes logic circuits 204, 206, 208 arranged in a vertical data path. Referring to FIG. 2A, the architecture 200 includes a set of bitslices 202 that perform a series of operations on respective bits 0-7. The operations include a first operation (Operation 1) implemented by logic circuits 204, a second operation (Operation 2) implemented by logic circuits 206 and performed on an output of the first operation, and a third operation (Operation 3) implemented by logic circuits 208 and performed on an output of the second operation. The operations may be any suitable operations to be performed on the data, e.g., a flop wordslice operation, a multiplex wordslice operation, a add wordslice operation, etc. In contrast the in-plane architecture 100 of FIG. 1, where the logic circuits 104, 106, 108 for each bitslice 102 are formed in the same plane, each bitslice 202 in the architecture 200 is formed in a different vertical plane, with the logic circuits performing the operations being formed between the metallization layers defined by the signal lines 210, 211. As shown, the signal lines 210 run in the left-to-right direction with respect to FIG. 2A, while the signal lines 211 run into and out of the page with respect to FIG. 2A. The logic circuits in the example architecture 200 may be formed using logic devices that do not include complementary metal oxide semiconductor (CMOS) technology (“non-CMOS devices” as used herein). Examples of non-CMOS devices may include, for example, ferroelectric field-effect transistor (FeFET) devices, spintronic logic devices (e.g., magnetoelectric spin orbit (MESO) devices), tunnel FETs, or spin wave devices.

Referring now to FIG. 2B, a chip 210 is shown coupled to a main board 214 similar to the example shown in FIG. 1B. However, as shown, the chip 210 includes a vertical data path architecture similar to the one shown in FIG. 2A, with bitslices 202 arranged in the vertical direction and formed between metallization layers 212 of the chip 210. In some embodiments, the chip 210 may include, for 8 bits, between 10-15, such as 16 layers with 10 fine pitched and 6 courser pitched layers.

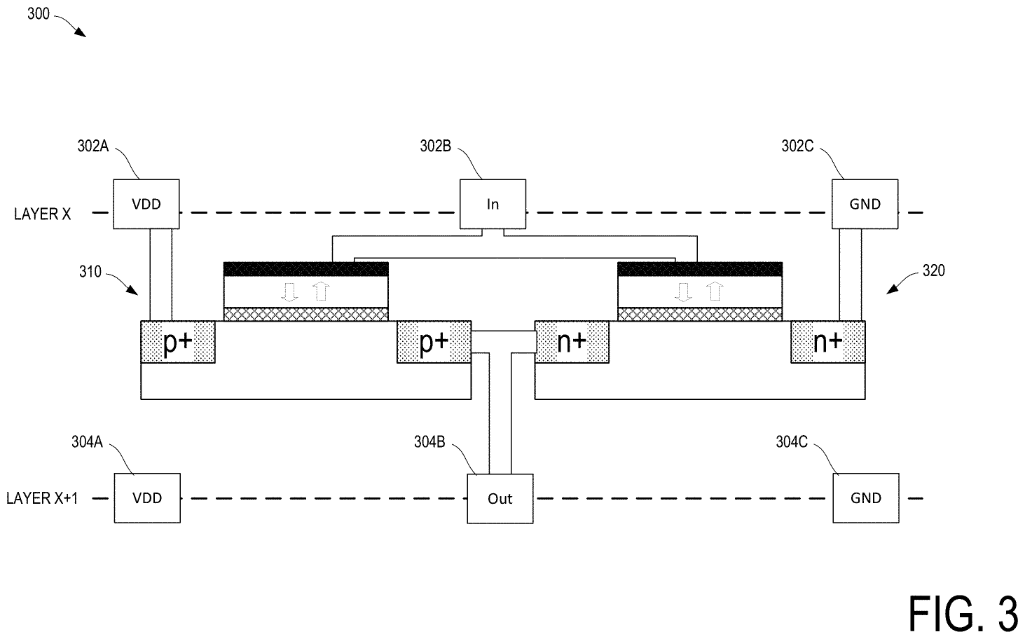

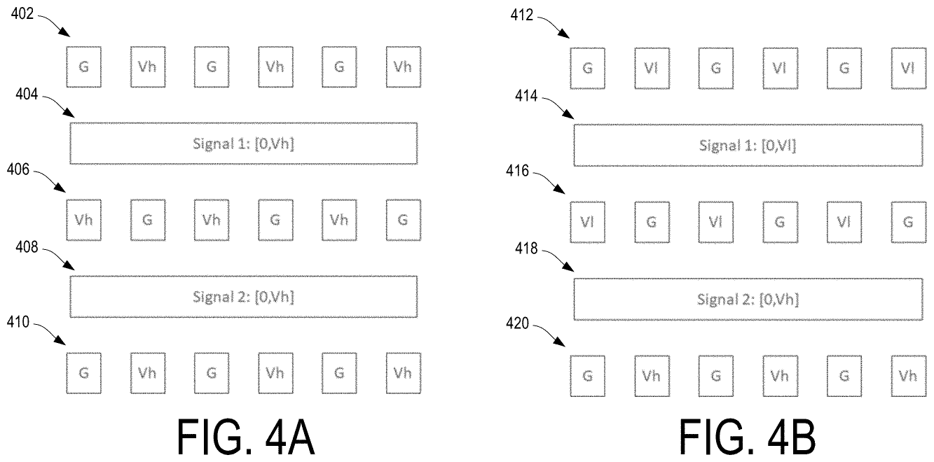

The metallization layers 212 may carry signals and/or supply voltages to the logic circuits in each bitslice, e.g., as shown in FIG. 3 and described below. The signal and voltage supply lines may be routed in an energy efficient manner, e.g., as shown in FIG. 4 and described below. In certain embodiments, power may be supplied to the voltage supply lines within the metallization layers 212A-G through vias that run to the side the die 210 that couples to the circuit board 214 (e.g., through the metallization layers 212H-N). In other embodiments, however, power may be supplied to the voltage supply lines within the metallization layers 212A-G through vias that run to the side the die 210 opposite the circuit board 214, e.g., to avoid unwanted interactions between the power delivery lines and the signal lines within the metallization layers 212H-N.

FIG. 3 illustrates an example logic circuit 300 formed between metallization layers in accordance with embodiments of the present disclosure. The example logic circuit 300 includes two FeFET transistors 310, 320 arranged in an inverter circuit formed between metallization layers X and X+1 of a chip, with the voltage supply and signal lines 302, 304 being routed in the metallization layers X and X+1.

FIGS. 4A-4B illustrate example wiring arrangements for voltage supply and signal lines in integrated circuit chips implemented with CMOS devices and with alternative types of devices (e.g., MESO, FeFET, tunnel FET, or spin wave devices), respectively. Because these alternative types of devices may utilize lower supply voltages (e.g., Vl in the examples shown) than CMOS-based devices (e.g., Vh in the examples shown), the arrangement of the metal voltage supply lines in the chip may have a great effect on energy consumption of the chip. In the example shown in FIG. 4A, which illustrates a cross-section of metallization layers by a vertical plane (i.e., perpendicular to the plane of the integrated circuit chip), for instance, the voltage supply lines 402, 406, 408 alternate between ground (G) and the supply voltage for the CMOS circuits (Vh), and the signal lines 404, 408 (which can be either 0/ground or Vh) are routed between the voltage supply lines. However, in the example shown in FIG. 4B, which illustrates a cross-section of metallization layers by a vertical plane (i.e., perpendicular to the plane of the integrated circuit chip), where non-CMOS logic devices are used with lower supply voltages, the routing must be more carefully chosen. In particular, low voltage signal lines may need to be surrounded with only lower voltage supply wires and not by any high voltage supply lines to avoid excess energy dissipation. For instance, in the example shown, the voltage supply lines 412, 416 only alternate between ground (G) and the lower supply voltage (Vl) rather than also including a supply line for the higher supply voltage (Vh), since those surround the signal line 414 that is either ground/0 or the lower supply voltage (Vl). The voltage supply lines for the higher voltage (Vh) are consolidated in the lines 418, closer to the signal line 418 that is either ground/0 or the higher supply voltage (Vh).

As an example, in typical current CMOS-based circuits, the supply voltage utilized on the chip may be, e.g., Vₕ=0.7V. Where C is the capacitance per unit length of a signal-to-supply or signal-to-ground line, e.g. C=100 aF/um, then energy dissipation to the supply and ground may each be defined by C*Vₕ2/2, giving a total energy dissipation of C*Vₕ2, which results in 100*0.7*0.7=49 pN with the example values above. However, where the alternative types of devices are used, there may be two supply voltages: a high voltage supply for CMOS devices in the chip, e.g., Vₕ=0.7V, and a low voltage supply for the alternative devices, e.g., Vₗ=0.1V. Using the routing shown in FIG. 4B, the dissipation to supply and dissipation to ground may each be defined by C*Vₗ2/2, giving a total dissipation of C*Vₗ2, which results in 100*0.1*0.1=1 pN with the same C value above. Thus, the routing shown in FIG. 4B is much lower than the CMOS-only scenario shown in FIG. 4A, allowing for large power savings in logic circuits that utilize non-CMOS according to the present disclosure.

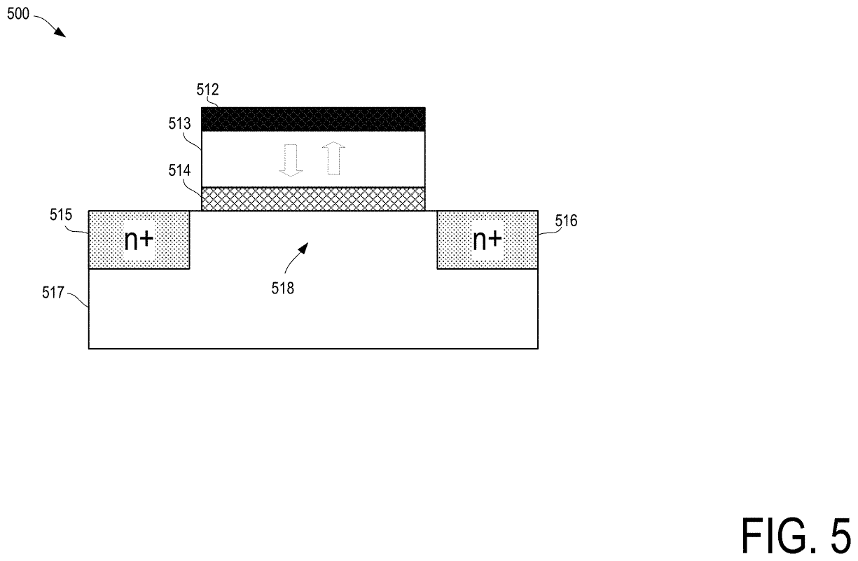

FIG. 5 illustrates an example n-channel FeFET 500 that may be implemented in vertically stacked logic circuits in accordance with embodiments of the present disclosure. The example n-channel FeFET 500 includes n-doped source/drain regions 515/516 in a substrate 517 (which may be p-doped in some instances), with electrodes formed on each source/drain region. The FeFET 500 further includes a dielectric layer 514 formed over a channel region 518 of the FeFET 500, a FE material 513 formed on the dielectric layer 514 and a gate electrode layer 512 formed on the FE material 513. The dielectric layer 514 may include any suitable dielectric material as described below, which in some instances, may include silicon and oxygen (e.g., silicon oxide (e.g., SiO₂)). The FE material 513 may include, in some instances, hafnium and oxygen (e.g., hafnium oxide (e.g., HfO₂)). The gate electrode layer 512 may include one or more metal-based layers, which may include one or more of polycrystalline silicon (Poly-Si), titanium, or nitrogen (e.g., a TiN layer and/or a Poly-Si layer). Although shown in FIG. 5 as a planar FET, certain embodiments may utilize non-planar FETs.

The FE material 513 may be polarized based on the following phenomenon. When an external electric field is applied across a ferroelectric (FE) film in a direction opposite its polarization, some FE domains reverse their polarization to form a critical nucleus, which then leads to the polarization switching of the entire FE film due to domain growth. The initial domain nucleation step behaves as a Poisson process and leads to the inherent stochasticity of the FE polarization switching. As the area of the FE film is scaled, this switching becomes discrete, eventually becoming a binary event where the FE polarization points either “up” or “down” with a probability that is dependent on the applied field. Thus, the polarization of the FE material 513 within the FeFET may be used to indicate a binary state, which may be used for indicating a state within a logic circuit.

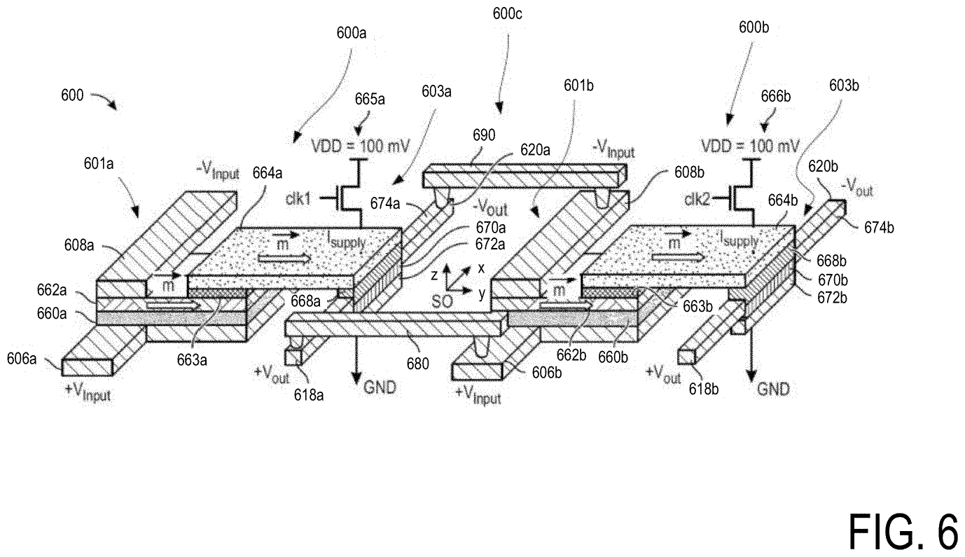

FIG. 6 illustrates an integrated circuit structure 600 including a set of example magnetoelectric spin orbit (MESO) logic devices 600a and 600b connected to one another in a cascaded fashion in accordance with embodiments of the present disclosure. An integrated circuit device assembly may include one or more of the integrated circuit structures of FIG. 6 and may further include a number of such MESO circuits cascaded with one another in the same manner as shown in FIG. 6. The shown devices may be structurally identical to one another, and electrically connected by way of a non-magnetic electrical conductor bridge 600c including non-magnetic electrical conductors 680 and 690. The description provided below will therefore relate to either of MESO device 600a or 600b, and/or to their respective components, by referring to the same in the alternative as, for example, MESO device 600a/600b. In addition, in the description of FIG. 6, “vertical” refers to the “z” direction, and “horizontal” refers to the “x” direction or the “y” direction, which directions are shown by way of the coordinate system provided in FIG. 6.

MESO device 600a/600b includes a magnetoelectric (ME) capacitor region 601a/601b, and a spin orbit (SO) module region 603a/603b magnetically coupled together. The ME capacitor region 601a/601b includes two non-magnetic electrical conductors 606a/606b (which is to provide a positive input bias or voltage, Vin+) and 608a/608b (which is to provide a negative input bias or voltage, Vin−), between which are provided a layer including a magnetoelectric material (ME layer) 660a/660b connected to Vin−, and a layer including a first ferromagnetic material (FM layer) 662a/662b.

The ME capacitor 601a/601b may be charged and discharged by virtue of the bias applied between Vin+ and Vin−. A charging and discharging of the ME capacitor region corresponds to a change in the information state of the ME capacitor. The ME capacitor region 601a/601b is coupled to the SO module 603a/603b by way of a non-magnetic electrical conductor structure including non-magnetic electrical conductors 680 and 690.

SO module 603a/603b includes a second FM layer 664a/664b disposed directly on a spin orbit coupling stack (SOC stack) including spin coherent layer 668a/668b and spin orbital coupling layer 670a/670b. Spin coherent layer 668a/668b, which in turn is disposed directly on a spin orbital coupling layer 670a in contact with a SO module non-magnetic electrical conductor 672a. SO module 603a/603b provides a structure that, when subjected to a supply current I_{supply} supplied by way of a transistor, such as the N-type Metal-Oxide-Semiconductor Field-Effect (NMOS) transistor 666a/666b, first converts the supply current I_{supply} to a spin current by virtue of I_{supply} contacting second FM layer 664a, and thereafter converts the spin current to an output supply current flowing horizontally in the positive or negative x direction depending on the magnetization direction of second FM layer 664a. Output charge current Iₒᵤₜₚᵤₜ of MESO device 600a generates a bias between Vin− and Vin+ of cascaded MESO device 600b as shown.

Second FM layer 664a is coupled to the first FM layer 662a by virtue of a coupling layer 663a. Coupling layer may include one or more of Fe₃O₄, CoFe₂O₄, EuO, Fe₂O₃, CO₂O₃, Co₂FeO₄, Ni₂FeO₄, (Ni,Co)₁₊₂ₓTi₁₋ₓO₃, yttrium iron garnet (YIG)=Y₃Fe₅O₁₂, (MgAl_{0.5}Fe_{1.5}O₄, MAFO), or (NiAFO, NiAlₓFe₂₋ₓO₄). The coupling layer is to electrically insulate the ME capacitor from the SO module (especially because of separate clocking of cascaded MESO devices as suggested for example by first and second clocking signals clk1 and clk2) while providing magnetic coupling between the first FM layer 662a and the second FM layer 664a. Coupling layer 663a serves to isolate the ME capacitor from the SO module electrically, especially because of separately clocking of the MESO devices as noted above.

Transistor 666a/666b, clocked using a clock signal clk1/clk2 at its gate, is to provide the supply current I_{supply} by virtue of a bias between V_{dd} and Ground (Gnd) as shown. I_{supply} is supplied vertically, in the minus z direction, to second FM layer 664a/664b. I_{supply} will have no spin polarization before reaching the second FM layer. By virtue of contacting the second FM layer however, a spin current is generated from the supply current, the spin current having a spin direction based on a magnetization direction in the second FM layer. In FIG. 6, magnetization direction is shown by way of arrows denoted “m.” The spin current will pass through the spin coherent layer 668a/668b and reach the interface between the spin coherent layer 668a/668b and the spin orbital coupling (SO coupling) layer 670a/670b. At the latter interface, the spin current will be converted into the output/spin orbital (SO) charge current I_{c} as shown. The SO charge current I_{c} flow creates a bias V_{Tout}+ at contact 618a and a bias Vₒᵤₜ− at contact 620a.

Because of the magnetic coupling provided by the coupling layer 663a/663b, first FM layer 662a/662b and second FM layer 664a/664b will have magnetization directions that are the same when a bias is applied to the ME capacitor 600a/600b. The direction of magnetization m, in the shown configuration, will be in the negative or positive y direction, since, in general, and unless other factors are at play, a magnetization direction in an object tends to be along a direction corresponding to a longest dimension of the object, in the shown case, in the y direction. When the magnetization direction m is changed, the functionality of the SO module is changed as well. As a result, with a change in the direction of magnetization of BML and TML, the direction of the SO charge current I_{c} can change as well. Therefore, changing the ME capacitor state will change the direction of the SO charge current I_{c}.

SO module 603a/603b operates based on spintronic phenomena, including a spin hall effect (SHE) and/or a Rashba-Edelstein effect (including inverses of each of the latter effects). SHE is based on the use of heavy metals to convert a spin current into a charge current, and vice versa in the inverse case.

Referring to the SO module 603a/603b, in the case of inverse SHE, I_{supply} going into the second FM layer 664a/664b will polarize the electrons of the supply current I_{supply} and generate a spin polarized current therefrom, where the spin movement of the electrons is based on the direction of magnetization m. Therefore, the SO module 603a/603b is configured to convert the magnetization state of the FM layers into a SO charge current I_{c}.

The current I_{c} can serve to charge a capacitor in the next cascaded MESO device by virtue of the generation of a voltage bias between contacts 618a and 620a as shown. Furthermore, it is to be understood that each of the MESO device shown, including 600b, can be used to charge a ME capacitor similar to ME capacitor 601a/601b at the next cascaded MESO device by virtue of the SO charge current I_{c} that it may generate and the resultant output voltage bias (e.g., at contacts 618b and 620b of MESO device 600b) at its output to form the logic circuit or part of a logic circuit, as shown in FIG. 6.

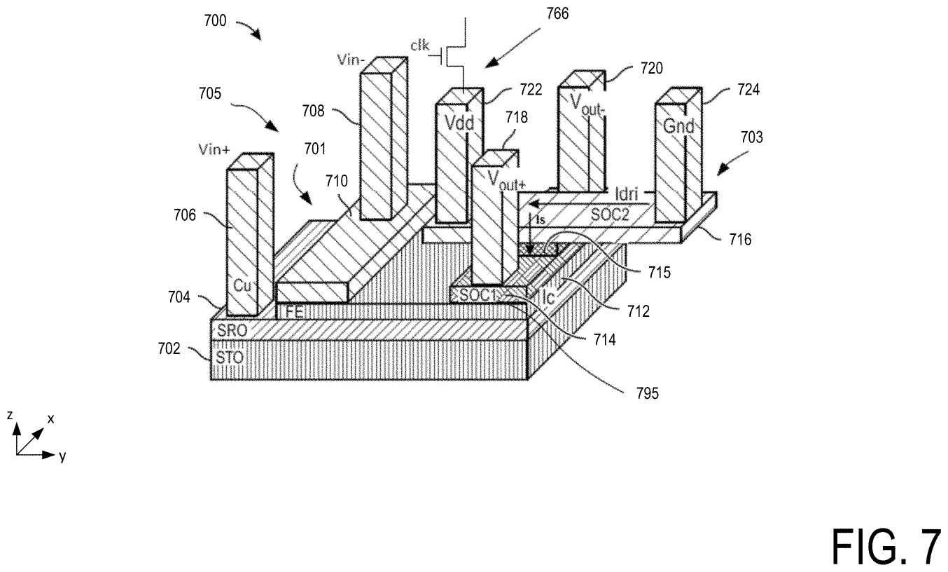

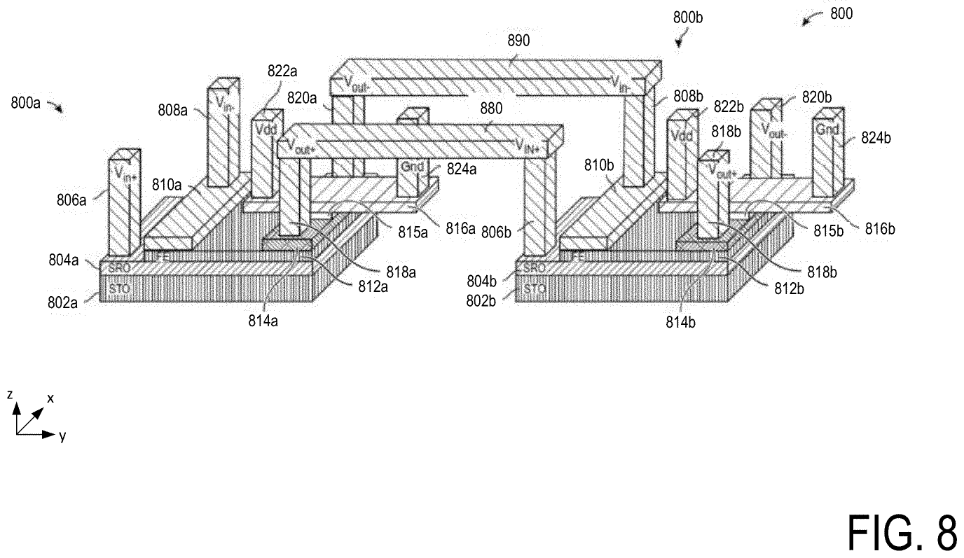

FIG. 7 illustrates an integrated circuit structure 700 including an example ferroelectric spin orbit logic (FSOL) device 705 in accordance with embodiments of the present disclosure. The FSOL device 700 may be configured to be electrically connected by way of a non-magnetic electrical conductor bridge to another similar or identical device in a cascaded fashion, as will be explained in further detail in the context of FIG. 8. In the description of FIG. 7, “vertical” refers to the “z” direction, and “horizontal” refers to the “x” direction or the “y” direction, which directions are shown by way of the coordinate system provided in FIG. 7.

FSOL device 700 includes a ferroelectric (FE) capacitor 701, and a spin orbit module (SOM) region 703 coupled together by virtue of an interface 795 between a layer of capacitor 701 including a ferroelectric (FE) material (FE layer) 712 and a first layer including a spin orbit coupling (SOC) material (SOC1 layer) 714 at the SOM region 703. The FE layer 712 may include a material such as at least one of BiFeO3, BaTiO3, Pb[ZrₓT₁₋ₓ]O₃, LuFeO3, or HfZrOx. The FE capacitor 701 includes the FE layer 712, a negative electrode layer 710 that is connected to a negative input contact Vᵢₙ− 708, and a positive electrode layer that corresponds to a layer including SrRuO3 (SRO layer) 704. SRO layer 704 is connected to a positive input Vᵢₙ+ conductive structure 706. Contacts Vᵢₙ+ and Vᵢₙ− are to provide a bias differential at each side of the FE layer 712. SRO layer 704 may be grown epitaxially onto a layer including silicon (Si) substrate buffered by SrTiO3 (STO) layer 702. since the FE material choice is greatly increased by embodiments, the bottom electrode including the SRO/STO layers can be replaced by many other material substrates or conducting materials compatible with various FE materials. The SRO layer or STO layer may include, for example, at least one of SrRuO3, SrVO3, SrCrO3, SrFeO3, ReO3, NaWO3, KMoO3, SrNbO3, LaTiO3, LaWO3. Non-stoichiometric as well as doped materials are also possible.

The FE capacitor 701 may be charged and discharged by virtue of the bias applied between Vᵢₙ+ and Vᵢₙ−. A charging and discharging of the FE capacitor corresponds to a change in the information state of the FE capacitor by virtue of a change in electric polarization within the FE material of FE layer 712. The FE capacitor 701 is coupled to the SOM 703 by way of an interface between FE layer 712 and SOC1 layer 714, where FE layer 712 and SOC1 layer 714 are coupled to one another such that an electric polarization direction of the FE layer 712 affects a direction of current flow I_{c} within the SOC1 layer as will be explained further below.

SOM 703 in turn includes a spin orbit coupling stack (SOC stack) that in turn comprises a first layer including a SOC material (SOC1 layer) 714, a second layer including a SOC material (SOC2 layer) 716, and a layer including a material to serve as a tunnel barrier (TB layer) 715, such as MgO or AlOx, or the like, between SOC1 layer 714 and SOC2 layer 716. Any of the SOC1 layer or SOC2 layer may include any of: a metal, such as W, Ta, or Pt; topological insulators such as Bi₂Se₃, Bi₂Te₃, BiSb; or materials containing 2-dimensional electron gas e.g. LaAlO3/SrTiO3 or Al/KTaO3 interfaces. As used herein, a “SOC material” is a material that has a spin Hall effect coefficient.

In some embodiments, either of SOC1 layer or SOC2 layer may comprise one or more layers. For example, either of SOC1 layer or SOC2 layer may comprise a SOC material, or a hetero-structure, which is characterized by being able to provide a Spin Hall effect or an inverse Spin Hall effect (SHE or inverse SHE). In some embodiments, either of SOC1 layer or SOC2 layer may comprise two-dimensional materials (2D) with spin orbit interaction. According to some embodiments, the first SOC material and the second SOC material are different from one another. According to some other embodiments, the first SOC material and the second SOC material are identical to one another.

In some embodiments, the 2D materials may be selected from a group consisting of: Graphene, MoS₂, WSe₂, WS₂, and MoSe₂ In some embodiments, the 2D materials include an absorbent selected from a group consisting of: Cu, Ag, Pt, Bi, Fr, and H absorbents.

In some embodiments, either of SOC1 layer or SOC2 layer may include materials ROCh₂, where ‘R’ is selected from a group consisting of: La, Ce, Pr, Nd, Sr, Sc, Ga, Al, and In, and where “Ch” is a chalcogenide selected from a group consisting of S, Se, and Te.

In some embodiments, either of SOC1 layer or SOC2 layer may include one or more material that form a hetero-structure with Cu, Ag, Al, and Au.

In some embodiments, either of SOC1 layer or SOC2 layer comprises a material selected from a group consisting of: β-Ta, β-W, W, Pt, Cu doped with Iridium, Cu doped with Bismuth, and Cu doped an element of 3d, 4d, 5d, 4f, or 5f of periodic table groups.

In some embodiments, either of SOC1 layer or SOC2 layer may include any combination of one or more layers of the materials described above in the context of SOC layers.

Any of the SOC1 layer and SOC2 layer may include one layer or multiple layers. The FE layer or TB layer may include a single layer. The FE layer may for example have a thickness of about 10 nm or less. The TB layer may be a few nm thicker than the FE layer. The layers do not have to have a rectangular cross section, and may have any cross section. For example, they can have rounded corners with similar functionality to that for rectangular cross sections.

In some embodiments, the spin-orbit mechanism responsible for spin-to-charge current conversion, such as that implemented by way of example spin orbit stack including layers 668a, 670a and 672a of FIG. 6, or such as that exhibited by SOC1 layer 714 of FIG. 7 described herein, is referred to as the inverse Spin Hall effect in a 2D electron gases.

For example, referring first to FIG. 7 and SOC2 layer 716, positive current I_{dri} along the −y direction produces a spin injection current Iₛ with transport direction for the spin along the −z direction and spins pointing to the +z direction, as expressed in Equation (1) below.

[symbol]

=θ· [symbol] ·\hat{σ} Eq. (1)

where θ is the spin Hall angle, and σ is the spin operator, which stands for spin polarization, a unitless quantity.

The above results in the generation of charge current I_{c} in SOC1 layer 714 proportional to the spin current Iₛ (the propagation of the spin without charge flow).

The spin-orbit interaction at an interface between SOC1 layer and SOC2 layer is brought about by the inverse Rashba-Edelstein Effect (IREE)) as referred to above (inverse SHE), producing a charge current I_{c} in the horizontal direction given as:

[symbol]

=θ· [symbol] ·\hat{σ} Eq. (3)

A mechanism of embodiments is to use the local electrical field generated by FE at the FE/SOC1 interface. This local electrical field will change the sign of θ, so that the current directionality of I_{c} will change based on the FE polarization state.

Referring still to FIG. 7, the TB layer 715 may include one or more layers of a dielectric oxide material, such as manganese oxide MgO, which is good at preserving the spin polarization, although other materials, such as, for example, aluminum oxide Al₂O₃ and silicon oxide SiO work as well. TB layer 715 may be in direct contact with SOC1 layer 714 at one side thereof, and with SOC2 layer at another side thereof. A role of TB layer 715 is to provide electrical isolation between SOC1 layer 714 and SOC2 layer 715. SOC1 layer 714 is coupled at one end thereof to a positive output contact Vₒᵤₜ+ 718, and at another end thereof to a negative output contact Vₒᵤₜ− 720. Vₒᵤₜ− and Vₒᵤₜ+ in FIG. 7 may correspond to the Vₒᵤₜ− 620a and Vₒᵤₜ+ 618a of FIG. 6 that may be connected to another FSOL device similar to FSOL device 700 by virtue of a bridge similar to bridge 600c of FIG. 6 as will be described in further detail in connection with FIG. 8 below.

SOM 703 provides a structure that, when subjected to a drive/supply current I_{dri}, for example supplied by way of a transistor, such as the N-type Metal-Oxide-Semiconductor Field-Effect (NMOS) transistor 766 similar to NMOS transistor 166a of FIG. 6, first converts the supply current I_{dri} to a spin current Iₛ by virtue of I_{supply} contacting SOC2 layer 716, and thereafter converts the spin current Iₛ to an output supply current I_{c} flowing horizontally in the positive or negative x direction in SOC2 layer 714 depending on the electric polarization direction within FE layer 712. Output charge current I_{c} of FSOL device 700 generates a bias between Vₒᵤₜ− and Vₒᵤₜ− and results in a similar bias in a cascaded FSOL device as will be explained in the context of FIG. 8 below.

Transistor 766, clocked using a clock signal clk at its gate, is to provide the drive current I_{dri} by virtue of a bias between V_{dd} at V_{dd} conductive structure 722 and Ground (Gnd) at Gnd conductive structure 724 as shown. As shown I_{dri} is supplied horizontally along SOC2 layer 716 between Gnd conductive structure 724 and V_{dd} conductive structure 722, in the minus y direction although embodiments are not so limited and the Gnd and V_{dd} contacts could be switched in their positions to have I_{dri} flow in the plus y direction. By virtue of contacting the SOC2 layer 716, a spin current Iₛ is generated from I_{dri}, the spin current Iₛ having a spin direction as dictated by the SOC2 layer 716. Spin current Iₛ will pass through the TB layer 715, and reach the interface 795 between the FE layer 712 and the SOC1 layer 714. At the latter interface, the spin current will be converted into the output/spin orbital (SO) charge current I_{c} as shown.

The direction of electric polarization in the FE layer 712 (controlled by the polarity of voltage (delta of Vᵢₙ+ and Vᵢₙ− across the FE layer) in the plus or minus z direction) will change the functionality of the SOM 703 by affecting the direction of flow of I_{c} within SOC1 layer. The direction of electric polarization in the FE layer 712 specifically influences the functionality of SOC1 layer 714 by virtue of the interface 795 between FE layer 712 and SOC1 layer 714, while SOC2 layer 716 is insulated from the direction of electric polarization in the FE layer 712 by virtue of TB layer 715. As a result, with a change in the direction of electric polarization of FE layer 712, the direction of the SO charge current I_{c} can change as well. Therefore, changing the FE capacitor state will change the direction of the SO charge current I_{c}.

While, in the embodiment of FIG. 6, the bias between Vᵢₙ− and Vᵢₙ+ would polarize the magnetic properties of the ME layer 160a, which in turn would affect the magnetization direction of the FM layers 662a and 664a, in the embodiment of FIG. 7, we do away with a magnetoelectric layer, the two FM layers 662a and 664a, and the coupling layer 663a therebetween, Instead, using FE capacitor 701, we polarize the FE layer 712 instead, without using a manipulation of magnetization direction in a FM layer. The electric field, as reflected in the direction of electric polarization in FE layer 621, would impinge on interface 795 with SOC1 layer 714, and influence/change the spin orbit coupling effect of the SOC1 material. Therefore, the embodiment of FIG. 7 involves spintronics without magnetics.

In some embodiments, such as those described above in FIG. 7, and to be described below in the context of FIG. 8, the contacts, electrodes, interconnects, and non-magnetic conductors may be formed of non-magnetic metal (e.g., Cu, Ag, etc.).

FIG. 8 illustrates an integrated circuit structure 800 including a cascaded FSOL logic circuit having a set of FSOL devices 800a and 800b electrically connected to one another in a cascaded fashion as shown. The FSOL devices 800a and 800b may be similar to the FSOL device 700 of FIG. 7. The shown devices may, similar to the cascaded arrangement of FIG. 6, be structurally identical to one another, and electrically connected by way of a non-magnetic electrical conductor bridge 800c including non-magnetic electrical conductors 880 and 890. The description provided above regarding FIG. 7 will therefore relate to either of FSOL devices 800a or 800b of FIG. 8, and/or to their respective components, with the difference being that a component with a reference numeral “x” in FIG. 7 is denoted “xa” for FSOL device 800a of FIG. 8, and “xb” for FSOL device 800b of FIG. 8. In addition, in the description of FIG. 8, similar to that of FIGS. 6 and 7, “vertical” refers to the “z” direction, and “horizontal” refers to the “x” direction or the “y” direction, which directions are shown by way of the coordinate system provided in FIG. 8.

In FIG. 8, the charge current I_{c} from FSOL device 800a (similar to FSOL device 700 of FIG. 7) may be carried by conductor bridge 800c in FIG. 8, which bridge includes conductors 880 and 890, similar to conductors 680 and 690 of bridge 600c of FIG. 6. I_{c} can serve to charge a capacitor in the next cascaded FSOL device 800b by virtue of the generation of a voltage bias between contacts 818a and 820a as shown. Furthermore, it is to be understood that each of the FSOL device shown, including 800b, can be used to charge a capacitor similar to capacitor 701 of FIG. 7 at the next cascaded FSOL device by virtue of the SO charge current I_{c} that it may generate and the resultant output voltage bias (e.g. at contacts 818b and 820b of FSOL device 800b) at its output to form the logic circuit or part of a logic circuit, as shown in FIG. 8.

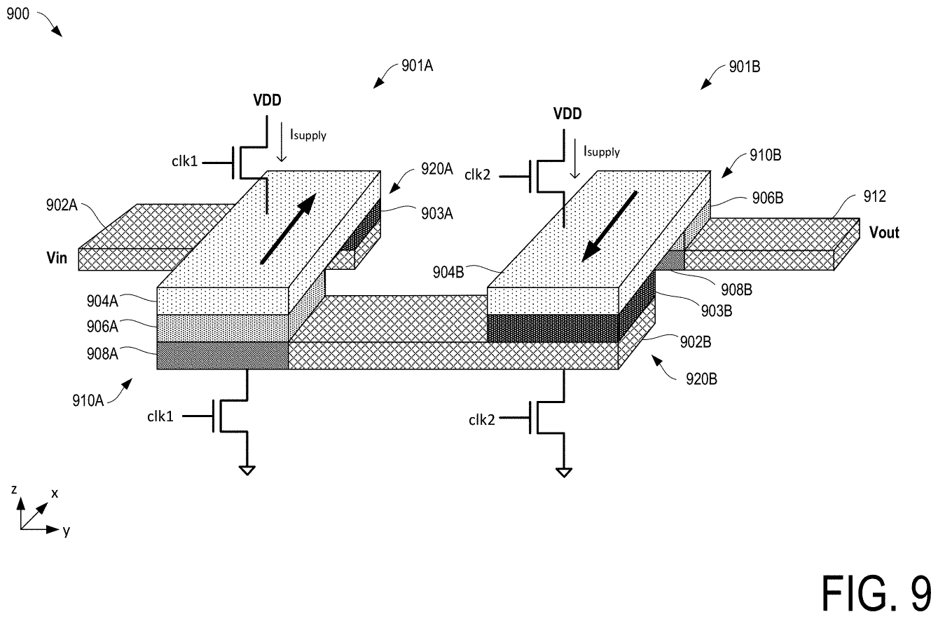

FIG. 9 illustrates another example integrated circuit structure 900 with two single input spintronic logic devices 901a/901b connected to one another in a cascaded fashion in accordance with embodiments of the present disclosure. The example spintronic logic devices 901 are single input devices, whereas the spintronic logic shown in FIGS. 6, and 7-8 are differential input devices. The shown devices may be structurally identical to one another. The description provided below will therefore relate to either of spintronic logic device 901a or 901b, and/or to their respective components, by referring to the same in the alternative as, for example, spintronic logic device 901a/901b. In addition, in the description of FIG. 9, “vertical” refers to the “z” direction, and “horizontal” refers to the “x” direction or the “y” direction, which directions are shown by way of the coordinate system provided in FIG. 6.

Each spintronic logic device 901 includes a spin orbital (SO) module region 910a/b and a magnetoelectric (ME) capacitor region 920a/b. The SO module region 910a/b includes a stack of materials that include a spin orbit coupling (SOC) material layer 908a/b, a spin coherent (SC) material layer 906a/b above the SOC layer 908a/b, and a ferromagnetic (FM) material layer 904a/b above the SC material layer 906a/b. The ME capacitor region 920a/b includes a stack of materials that includes a non-magnetic metal material layer 902a/b, a magnetoelectric (ME) material layer 903a/b above the non-magnetic metal material layer 902a/b, and the FM material layer 904a/b above the ME material layer 903a/b. In the example devices, spins injected from the ferromagnet (FM) material layer 903a/b in the vertical direction with spin polarization along the in-plane direction cause a topologically generated charge current in the SOC material layer 908a/b. Injecting a spin current polarized along the in-plane direction overpopulates the Fermi surface on one side of the topological material compared to the other side, generating a net charge current in the y direction. The conversion has the right symmetry to convert the information of the FM material layer to a current output. Thus, the state of the devices 901a/b can be encoded based on the magnetization of the FM material layers.

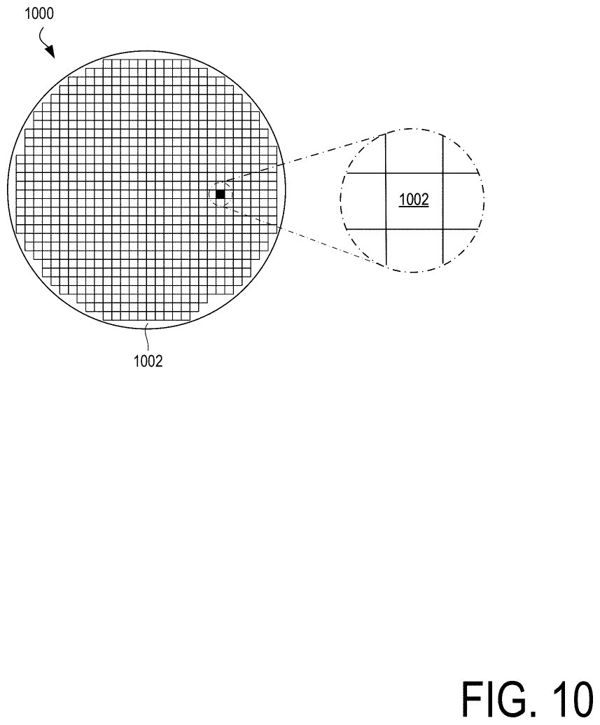

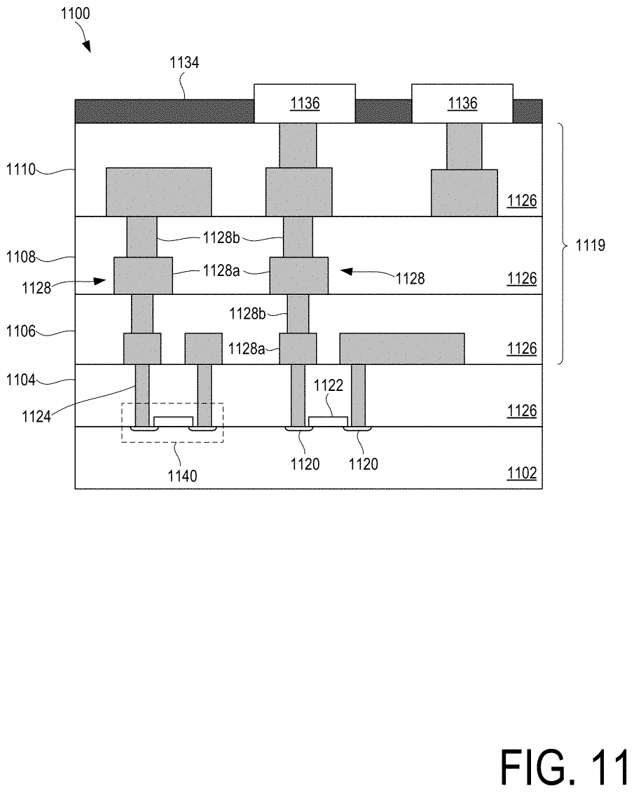

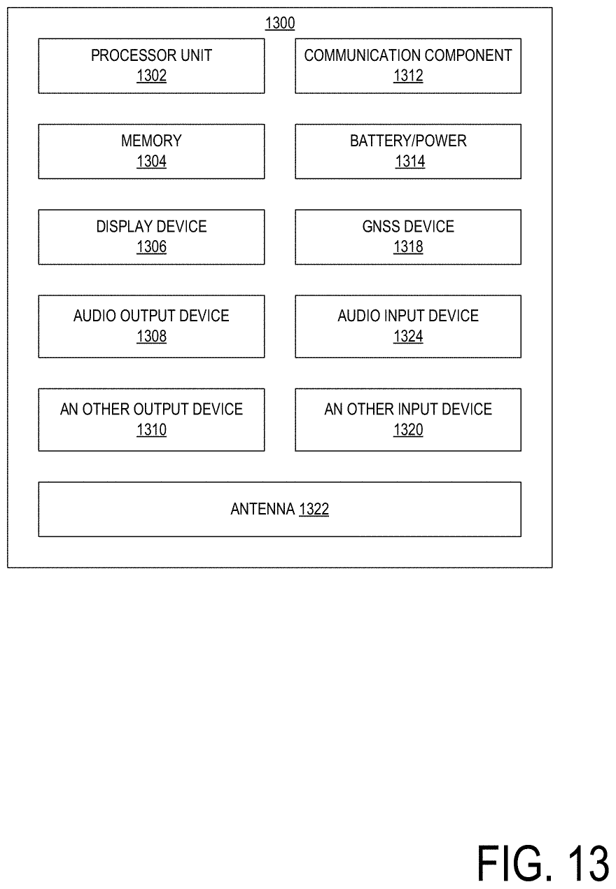

FIG. 10 is a top view of a wafer 1000 and dies 1002 that may incorporate any of the embodiments disclosed herein. The wafer 1000 may be composed of semiconductor material and may include one or more dies 1002 having integrated circuit structures formed on a surface of the wafer 1000. The individual dies 1002 may be a repeating unit of an integrated circuit product that includes any suitable integrated circuit. After the fabrication of the semiconductor product is complete, the wafer 1000 may undergo a singulation process in which the dies 1002 are separated from one another to provide discrete “chips” of the integrated circuit product. The die 1002 may include one or more transistors (e.g., some of the transistors 1140 of FIG. 11, discussed below), supporting circuitry to route electrical signals to the transistors, passive components (e.g., signal traces, resistors, capacitors, or inductors), and/or any other integrated circuit components. In some embodiments, the wafer 1000 or the die 1002 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1002. For example, a memory array formed by multiple memory devices may be formed on a same die 1002 as a processor unit (e.g., the processor unit 1302 of FIG. 13) or other logic that is configured to store information in the memory devices or execute instructions stored in the memory array.

FIG. 11 is a cross-sectional side view of an integrated circuit device 1100 that may be included in any of the embodiments disclosed herein. One or more of the integrated circuit devices 1100 may be included in one or more dies 1002 (FIG. 10). The integrated circuit device 1100 may be formed on a die substrate 1102 (e.g., the wafer 1000 of FIG. 10) and may be included in a die (e.g., the die 1002 of FIG. 10). The die substrate 1102 may be a semiconductor substrate composed of semiconductor material systems including, for example, n-type or p-type materials systems (or a combination of both). The die substrate 1102 may include, for example, a crystalline substrate formed using a bulk silicon or a silicon-on-insulator (SOI) substructure. In some embodiments, the die substrate 1102 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1102. Although a few examples of materials from which the die substrate 1102 may be formed are described here, any material that may serve as a foundation for an integrated circuit device 1100 may be used. The die substrate 1102 may be part of a singulated die (e.g., the dies 1002 of FIG. 10) or a wafer (e.g., the wafer 1000 of FIG. 10).

The integrated circuit device 1100 may include one or more device layers 1104 disposed on the die substrate 1102. The device layer 1104 may include features of one or more transistors 1140 (e.g., metal oxide semiconductor field-effect transistors (MOSFETs)) formed on the die substrate 1102. The transistors 1140 may include, for example, one or more source and/or drain (S/D) regions 1120, a gate 1122 to control current flow between the S/D regions 1120, and one or more S/D contacts 1124 to route electrical signals to/from the S/D regions 1120. The transistors 1140 may include additional features not depicted for the sake of clarity, such as device isolation regions, gate contacts, and the like. The transistors 1140 are not limited to the type and configuration depicted in FIG. 11 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 11, a transistor 1140 may include a gate 1122 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1140 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1140 along the source-channel-drain direction, the gate electrode may consist of a U-shaped structure that includes a bottom portion substantially parallel to the surface of the die substrate 1102 and two sidewall portions that are substantially perpendicular to the top surface of the die substrate 1102. In other embodiments, at least one of the metal layers that form the gate electrode may simply be a planar layer that is substantially parallel to the top surface of the die substrate 1102 and does not include sidewall portions substantially perpendicular to the top surface of the die substrate 1102. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1120 may be formed within the die substrate 1102 adjacent to the gate 1122 of individual transistors 1140. The S/D regions 1120 may be formed using an implantation/diffusion process or an etching/deposition process, for example. In the former process, dopants such as boron, aluminum, antimony, phosphorous, or arsenic may be ion-implanted into the die substrate 1102 to form the S/D regions 1120. An annealing process that activates the dopants and causes them to diffuse farther into the die substrate 1102 may follow the ion-implantation process. In the latter process, the die substrate 1102 may first be etched to form recesses at the locations of the S/D regions 1120. An epitaxial deposition process may then be carried out to fill the recesses with material that is used to fabricate the S/D regions 1120. In some implementations, the S/D regions 1120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1120 may be formed using one or more alternate semiconductor materials such as germanium or a group III-V material or alloy. In further embodiments, one or more layers of metal and/or metal alloys may be used to form the S/D regions 1120.

Electrical signals, such as power and/or input/output (I/O) signals, may be routed to and/or from the devices (e.g., transistors 1140) of the device layer 1104 through one or more interconnect layers disposed on the device layer 1104 (illustrated in FIG. 11 as interconnect layers 1106-1110). For example, electrically conductive features of the device layer 1104 (e.g., the gate 1122 and the S/D contacts 1124) may be electrically coupled with the interconnect structures 1128 of the interconnect layers 1106-1110. The one or more interconnect layers 1106-1110 may form a metallization stack (also referred to as an “ILD stack”) 1119 of the integrated circuit device 1100.

The interconnect structures 1128 may be arranged within the interconnect layers 1106-1110 to route electrical signals according to a wide variety of designs; in particular, the arrangement is not limited to the particular configuration of interconnect structures 1128 depicted in FIG. 11. Although a particular number of interconnect layers 1106-1110 is depicted in FIG. 11, embodiments of the present disclosure include integrated circuit devices having more or fewer interconnect layers than depicted.

In some embodiments, the interconnect structures 1128 may include lines 1128a and/or vias 1128b filled with an electrically conductive material such as a metal. The lines 1128a may be arranged to route electrical signals in a direction of a plane that is substantially parallel with a surface of the die substrate 1102 upon which the device layer 1104 is formed. For example, the lines 1128a may route electrical signals in a direction in and out of the page and/or in a direction across the page from the perspective of FIG. 11. The vias 1128b may be arranged to route electrical signals in a direction of a plane that is substantially perpendicular to the surface of the die substrate 1102 upon which the device layer 1104 is formed. In some embodiments, the vias 1128b may electrically couple lines 1128a of different interconnect layers 1106-1110 together.

The interconnect layers 1106-1110 may include a dielectric material 1126 disposed between the interconnect structures 1128, as shown in FIG. 11. In some embodiments, dielectric material 1126 disposed between the interconnect structures 1128 in different ones of the interconnect layers 1106-1110 may have different compositions; in other embodiments, the composition of the dielectric material 1126 between different interconnect layers 1106-1110 may be the same. The device layer 1104 may include a dielectric material 1126 disposed between the transistors 1140 and a bottom layer of the metallization stack as well. The dielectric material 1126 included in the device layer 1104 may have a different composition than the dielectric material 1126 included in the interconnect layers 1106-1110; in other embodiments, the composition of the dielectric material 1126 in the device layer 1104 may be the same as a dielectric material 1126 included in any one of the interconnect layers 1106-1110.

A first interconnect layer 1106 (referred to as Metal 1 or “M1”) may be formed directly on the device layer 1104. In some embodiments, the first interconnect layer 1106 may include lines 1128a and/or vias 1128b, as shown. The lines 1128a of the first interconnect layer 1106 may be coupled with contacts (e.g., the S/D contacts 1124) of the device layer 1104. The vias 1128b of the first interconnect layer 1106 may be coupled with the lines 1128a of a second interconnect layer 1108.

The second interconnect layer 1108 (referred to as Metal 2 or “M2”) may be formed directly on the first interconnect layer 1106. In some embodiments, the second interconnect layer 1108 may include via 1128b to couple the lines 1128 of the second interconnect layer 1108 with the lines 1128a of a third interconnect layer 1110. Although the lines 1128a and the vias 1128b are structurally delineated with a line within individual interconnect layers for the sake of clarity, the lines 1128a and the vias 1128b may be structurally and/or materially contiguous (e.g., simultaneously filled during a dual-damascene process) in some embodiments.

The third interconnect layer 1110 (referred to as Metal 3 or “M3”) (and additional interconnect layers, as desired) may be formed in succession on the second interconnect layer 1108 according to similar techniques and configurations described in connection with the second interconnect layer 1108 or the first interconnect layer 1106. In some embodiments, the interconnect layers that are “higher up” in the metallization stack 1119 in the integrated circuit device 1100 (i.e., farther away from the device layer 1104) may be thicker that the interconnect layers that are lower in the metallization stack 1119, with lines 1128a and vias 1128b in the higher interconnect layers being thicker than those in the lower interconnect layers.

The integrated circuit device 1100 may include a solder resist material 1134 (e.g., polyimide or similar material) and one or more conductive contacts 1136 formed on the interconnect layers 1106-1110. In FIG. 11, the conductive contacts 1136 are illustrated as taking the form of bond pads. The conductive contacts 1136 may be electrically coupled with the interconnect structures 1128 and configured to route the electrical signals of the transistor(s) 1140 to external devices. For example, solder bonds may be formed on the one or more conductive contacts 1136 to mechanically and/or electrically couple an integrated circuit die including the integrated circuit device 1100 with another component (e.g., a printed circuit board). The integrated circuit device 1100 may include additional or alternate structures to route the electrical signals from the interconnect layers 1106-1110; for example, the conductive contacts 1136 may include other analogous features (e.g., posts) that route the electrical signals to external components.

In some embodiments in which the integrated circuit device 1100 is a double-sided die, the integrated circuit device 1100 may include another metallization stack (not shown) on the opposite side of the device layer(s) 1104. This metallization stack may include multiple interconnect layers as discussed above with reference to the interconnect layers 1106-1110, to provide conductive pathways (e.g., including conductive lines and vias) between the device layer(s) 1104 and additional conductive contacts (not shown) on the opposite side of the integrated circuit device 1100 from the conductive contacts 1136.

In other embodiments in which the integrated circuit device 1100 is a double-sided die, the integrated circuit device 1100 may include one or more through silicon vias (TSVs) through the die substrate 1102; these TSVs may make contact with the device layer(s) 1104, and may provide conductive pathways between the device layer(s) 1104 and additional conductive contacts (not shown) on the opposite side of the integrated circuit device 1100 from the conductive contacts 1136. In some embodiments, TSVs extending through the substrate can be used for routing power and ground signals from conductive contacts on the opposite side of the integrated circuit device 1100 from the conductive contacts 1136 to the transistors 1140 and any other components integrated into the die 1100, and the metallization stack 1119 can be used to route I/O signals from the conductive contacts 1136 to transistors 1140 and any other components integrated into the die 1100.

Multiple integrated circuit devices 1100 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

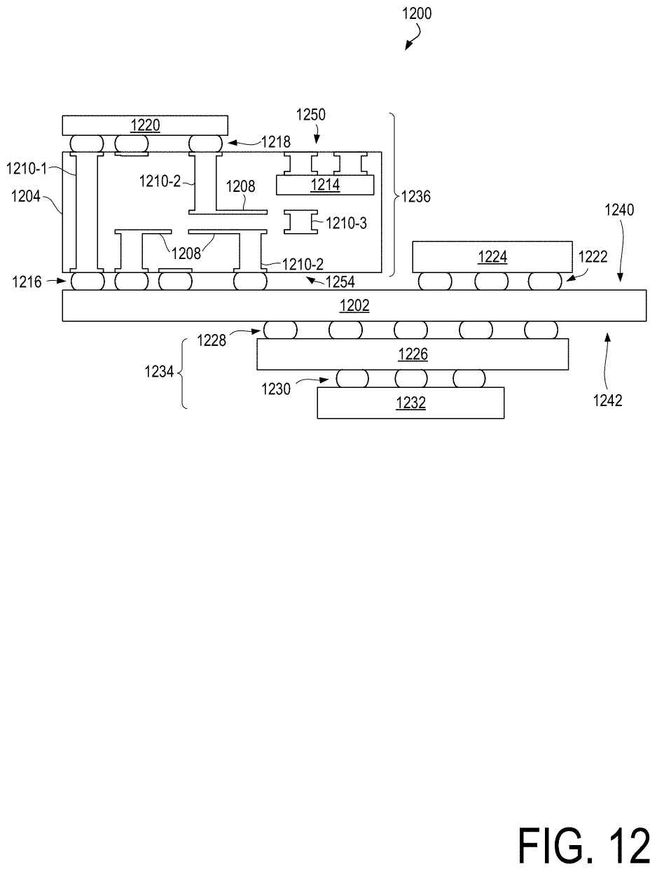

FIG. 12 is a cross-sectional side view of an integrated circuit device assembly 1200 that may include any of the embodiments disclosed herein. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpacked integrated circuit product that includes one or more integrated circuit dies (e.g., the die 1002 of FIG. 10, the integrated circuit device 1100 of FIG. 11) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art. In embodiments where the interposer is a non-printed circuit board

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include one or more of the embodiments disclosed herein. For example, any suitable ones of the components of the electrical device 1300 may include one or more of the integrated circuit device assemblies 1200, integrated circuit components 1220, integrated circuit devices 1100, or integrated circuit dies 1002 disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include another input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example A1 includes an integrated circuit apparatus comprising: a plurality of metallization layers, each metallization layer comprising voltage supply lines and signal lines; sets of logic circuits formed between respective pairs of metallization layers, each logic circuit set comprising non-CMOS logic devices arranged to perform a series of operations on respective bit of an input set of bits.

Example A2 includes the subject matter of Example A1, wherein the non-CMOS logic devices include ferroelectric field-effect transistor (FeFET) devices.

Example A3 includes the subject matter of Example A1, wherein the non-CMOS logic devices include spintronic logic devices.

Example A4 includes the subject matter of Example A3, wherein the spintronic logic devices include magnetoelectric spin orbit (MESO) devices.

Example A5 includes the subject matter of Example A3, wherein at least one spintronic logic device comprises: an electrically conductive layer; a ferromagnetic layer; a magnetoelectric layer disposed at least partially between the electrically conductive layer and the ferromagnetic layer; a spin orbit coupling (SOC) material; and a non-magnetic electrical conductor at least partially between the SOC material and the ferromagnetic layer.

Example A6 includes the subject matter of Example A3, wherein at least one spintronic logic device comprises: an electrically conductive layer; a first ferromagnetic layer; a second ferromagnetic layer; a magnetoelectric layer disposed at least partially between the electrically conductive layer and the first ferromagnetic layer; an insulating layer between the first ferromagnetic layer and the second ferromagnetic layer; a spin orbit coupling (SOC) material; and a non-magnetic electrical conductor at least partially between the SOC material and the second ferromagnetic layer.

Example A7 includes the subject matter of Example A6, wherein the electrically conductive layer is a first electrically conductive layer, the apparatus further comprises a second electrically conductive layer, and the first ferromagnetic layer and the magnetoelectric layer are between the first electrically conductive layer and the second electrically conductive layer.

Example A8 includes the subject matter of Example A3, wherein the spintronic logic devices comprise ferroelectric spin orbit logic (FSOL) devices.

Example A9 includes the subject matter of Example A3, wherein at least one spintronic logic device comprises: a first electrically conductive layer; a layer comprising a ferroelectric material (FE layer) on the first electrically conductive layer; a second electrically conductive layer on the FE layer; and a spin orbit coupling (SOC) stack including a first layer (SOC1 layer) including a first SOC material, and a second layer (SOC2 layer) including a second SOC material, the SOC1 layer adjacent the FE layer.

Example A10 includes the subject matter of any one of Examples A1-A9, wherein each set of logic circuits is formed on a different vertical plane within the apparatus.

Example A11 includes the subject matter of any one of Examples A1-A10, wherein each set of logic circuits includes a first logic circuit to perform a first operation and a second logic circuit to perform a second operation based on an output of the first operation.

Example A12 includes the subject matter of any one of Examples A1-A11, wherein the set of input bits comprises eight bits and the apparatus comprises eight logic circuit sets.

Example A13 includes the subject matter of any one of Examples A1-A12, wherein the voltage supply lines of the metallization layers include a first set of voltage supply lines to carry a first voltage, a second set of voltage supply lines to carry a second voltage, and a third set of voltage supply lines to connect to a ground signal, wherein the first set of voltage supply lines and second set of voltage supply lines are not routed in the same metallization layer.

Example A14 includes a chip package comprising: a package substrate; and an integrated circuit apparatus coupled to the package substrate, the integrated circuit apparatus according to any one of Examples A1-A13.

Example A15 includes a system comprising: memory; and a processor unit comprising an integrated circuit apparatus according to any one of Examples A1-A13.

Example B1 is an integrated circuit apparatus comprising: a plurality of metallization layers, each metallization layer on a different respective vertical plane within the apparatus; a first logic circuit formed between a first metallization layer and a second metallization layer, the first logic circuit comprising non-CMOS logic devices; and a second logic circuit formed between the second metallization layer and a third metallization layer, the second logic circuit comprising non-CMOS logic devices.

Example B2 includes the subject matter of Example B1, wherein the non-CMOS logic devices include ferroelectric field-effect transistor (FeFET) devices.

Example B3 includes the subject matter of Example B1, wherein the non-CMOS logic devices include spintronic logic devices.

Example B4 includes the subject matter of Example B3, wherein the spintronic logic devices include magnetoelectric spin orbit (MESO) devices.

Example B5 includes the subject matter of Example B3, wherein at least one spintronic logic device comprises: an electrically conductive layer; a ferromagnetic layer; a magnetoelectric layer disposed at least partially between the electrically conductive layer and the ferromagnetic layer; a spin orbit coupling (SOC) material; and a non-magnetic electrical conductor at least partially between the SOC material and the ferromagnetic layer.

Example B6 includes the subject matter of Example B3, wherein at least one spintronic logic device comprises: an electrically conductive layer; a first ferromagnetic layer; a second ferromagnetic layer; a magnetoelectric layer disposed at least partially between the electrically conductive layer and the first ferromagnetic layer; an insulating layer between the first ferromagnetic layer and the second ferromagnetic layer; a spin orbit coupling (SOC) material; and a non-magnetic electrical conductor at least partially between the SOC material and the second ferromagnetic layer.

Example B7 includes the subject matter of Example B6, wherein the electrically conductive layer is a first electrically conductive layer, the apparatus further comprises a second electrically conductive layer, and the first ferromagnetic layer and the magnetoelectric layer are between the first electrically conductive layer and the second electrically conductive layer.

Example B8 includes the subject matter of Example B3, wherein the spintronic logic devices comprise ferroelectric spin orbit logic (FSOL) devices.

Example B9 includes the subject matter of Example B3, wherein at least one spintronic logic device comprises: a first electrically conductive layer; a layer comprising a ferroelectric material (FE layer) on the first electrically conductive layer; a second electrically conductive layer on the FE layer; and a spin orbit coupling (SOC) stack including a first layer (SOC1 layer) including a first SOC material, and a second layer (SOC2 layer) including a second SOC material, the SOC1 layer adjacent the FE layer.

Example B10 includes the subject matter of Example B1, further comprising: a third logic circuit formed between the first metallization layer and the second metallization layer, the third logic circuit comprising non-CMOS logic devices to receive an output signal from the first logic circuit; and a fourth logic circuit formed between the second metallization layer and the third metallization layer, the fourth logic circuit comprising non-CMOS logic devices to receive an output signal from the second logic circuit.

Example B11 includes the subject matter of Example B1, wherein each metallization layer comprises voltage supply lines and signal lines, the voltage supply lines of the metallization layers include a first set of voltage supply lines to carry a first voltage and a second set of voltage supply lines to carry a second voltage, the first set of voltage supply lines and second set of voltage supply lines are not routed in the same metallization layer.

Example B12 is a chip package comprising: a package substrate; an integrated circuit die coupled to the package substrate, the integrated circuit die comprising: a first logic circuit formed between a first metallization layer of the die and a second metallization layer of the die, the first logic circuit comprising non-CMOS logic devices; and a second logic circuit formed between the second metallization layer and a third metallization layer of the die, the second logic circuit comprising non-CMOS logic devices; wherein the first logic circuit is formed on a different vertical plane within the integrated circuit die than the second logic circuit.

Example B13 includes the subject matter of Example B12, wherein the non-CMOS logic devices include ferroelectric field-effect transistor (FeFET) devices.

Example B14 includes the subject matter of Example B12, wherein the non-CMOS logic devices include spintronic logic devices.

Example B15 includes the subject matter of Example B14, wherein the spintronic logic devices include magnetoelectric spin orbit (MESO) devices.

Example B16 includes the subject matter of Example B14, wherein the spintronic logic devices comprise ferroelectric spin orbit logic (FSOL) devices.

Example B17 includes the subject matter of Example B12, wherein the integrated circuit die further comprises: a third logic circuit formed between the first metallization layer and the second metallization layer, the third logic circuit comprising non-CMOS logic devices to receive an output signal from the first logic circuit; and a fourth logic circuit formed between the second metallization layer and the third metallization layer, the fourth logic circuit comprising non-CMOS logic devices to receive an output signal from the second logic circuit.

Example B18 includes the subject matter of Example B12, wherein each metallization layer comprises voltage supply lines and signal lines, the voltage supply lines of the metallization layers comprising a first set of voltage supply lines to carry a first voltage and a second set of voltage supply lines to carry a second voltage, wherein the first set of voltage supply lines and second set of voltage supply lines are not routed in the same metallization layer.

Example B19 includes the subject matter of Example B18, wherein the voltage supply lines connect to electrical connections on a side of the integrated circuit die opposite a side of the integrated circuit die coupled to the package substrate.

Example B20 is a system comprising: a processor comprising: a plurality of metallization layers comprising voltage supply lines and signal lines, each metallization layer on a different respective vertical plane within the processor; a plurality of logic circuits, each logic circuit comprising non-CMOS logic devices and formed between respective pairs of metallization layers.

Example B21 includes the subject matter of Example B20, wherein the non-CMOS logic devices include ferroelectric field-effect transistor (FeFET) devices.

Example B22 includes the subject matter of Example B20, wherein the non-CMOS logic devices include spintronic logic devices.

Example B23 includes the subject matter of Example B20, wherein each set of logic circuits is formed on a different vertical plane within the processor.

Example B24 includes the subject matter of Example B20, wherein the voltage supply lines comprise a first set of voltage supply lines to carry a first voltage and a second set of voltage supply lines to carry a second voltage, wherein the first set of voltage supply lines and second set of voltage supply lines are routed in different metallization layers.

Example B25 includes the subject matter of Example B20, wherein the plurality of logic circuits comprise: a first logic circuit formed between a first metallization layer of the processor and a second metallization layer of the processor, the first logic circuit comprising non-CMOS logic devices; and a second logic circuit formed between the second metallization layer and a third metallization layer of the processor, the second logic circuit comprising non-CMOS logic devices.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An integrated circuit apparatus comprising:
a plurality of metallization layers, each metallization layer on a different respective vertical plane within the apparatus;
a first logic circuit formed between a first metallization layer and a second metallization layer, the first logic circuit comprising non-CMOS logic devices; and
a second logic circuit formed between the second metallization layer and a third metallization layer, the second logic circuit comprising non-CMOS logic devices.

2. The apparatus of claim 1, wherein the non-CMOS logic devices include ferroelectric field-effect transistor (FeFET) devices.

3. The apparatus of claim 1, wherein the non-CMOS logic devices include spintronic logic devices.

4. The apparatus of claim 3, wherein the spintronic logic devices include magnetoelectric spin orbit (MESO) devices.

5. The apparatus of claim 3, wherein at least one spintronic logic device comprises:
an electrically conductive layer;
a ferromagnetic layer;
a magnetoelectric layer disposed at least partially between the electrically conductive layer and the ferromagnetic layer;
a spin orbit coupling (SOC) material; and
a non-magnetic electrical conductor at least partially between the SOC material and the ferromagnetic layer.

6. The apparatus of claim 3, wherein at least one spintronic logic device comprises:
an electrically conductive layer;
a first ferromagnetic layer;
a second ferromagnetic layer;
a magnetoelectric layer disposed at least partially between the electrically conductive layer and the first ferromagnetic layer;
an insulating layer between the first ferromagnetic layer and the second ferromagnetic layer;
a spin orbit coupling (SOC) material; and
a non-magnetic electrical conductor at least partially between the SOC material and the second ferromagnetic layer.

7. The apparatus of claim 6, wherein the electrically conductive layer is a first electrically conductive layer, the apparatus further comprises a second electrically conductive layer, and the first ferromagnetic layer and the magnetoelectric layer are between the first electrically conductive layer and the second electrically conductive layer.

8. The apparatus of claim 3, wherein the spintronic logic devices comprise ferroelectric spin orbit logic (FSOL) devices.

9. The apparatus of claim 3, wherein at least one spintronic logic device comprises:
a first electrically conductive layer;
a layer comprising a ferroelectric material (FE layer) on the first electrically conductive layer;
a second electrically conductive layer on the FE layer; and
a spin orbit coupling (SOC) stack including a first layer (SOC1 layer) including a first SOC material, and a second layer (SOC2 layer) including a second SOC material, the SOC1 layer adjacent the FE layer.

10. The apparatus of claim 1, further comprising:
a third logic circuit formed between the first metallization layer and the second metallization layer, the third logic circuit comprising non-CMOS logic devices to receive an output signal from the first logic circuit; and
a fourth logic circuit formed between the second metallization layer and the third metallization layer, the fourth logic circuit comprising non-CMOS logic devices to receive an output signal from the second logic circuit.

11. The apparatus of claim 1, wherein each metallization layer comprises voltage supply lines and signal lines, the voltage supply lines of the metallization layers include a first set of voltage supply lines to carry a first voltage and a second set of voltage supply lines to carry a second voltage, the first set of voltage supply lines and second set of voltage supply lines are not routed in the same metallization layer.

12. A chip package comprising:
a package substrate;
an integrated circuit die coupled to the package substrate, the integrated circuit die comprising:
a first logic circuit formed between a first metallization layer of the die and a second metallization layer of the die, the first logic circuit comprising non-CMOS logic devices; and
a second logic circuit formed between the second metallization layer and a third metallization layer of the die, the second logic circuit comprising non-CMOS logic devices;
wherein the first logic circuit is formed on a different vertical plane within the integrated circuit die than the second logic circuit.

13. The chip package of claim 12, wherein the non-CMOS logic devices include ferroelectric field-effect transistor (FeFET) devices.

14. The chip package of claim 12, wherein the non-CMOS logic devices include spintronic logic devices.

15. The chip package of claim 14, wherein the spintronic logic devices include magnetoelectric spin orbit (MESO) devices.

16. The chip package of claim 14, wherein the spintronic logic devices comprise ferroelectric spin orbit logic (FSOL) devices.

17. The chip package of claim 12, wherein the integrated circuit die further comprises:
a third logic circuit formed between the first metallization layer and the second metallization layer, the third logic circuit comprising non-CMOS logic devices to receive an first output signal from the first logic circuit; and
a fourth logic circuit formed between the second metallization layer and the third metallization layer, the fourth logic circuit comprising non-CMOS logic devices to receive an output signal from the second logic circuit.

18. The chip package of claim 12, wherein each metallization layer comprises voltage supply lines and signal lines, the voltage supply lines of the metallization layers comprising a first set of voltage supply lines to carry a first voltage and a second set of voltage supply lines to carry a second voltage, wherein the first set of voltage supply lines and second set of voltage supply lines are not routed in the same metallization layer.

19. The chip package of claim 18, wherein the voltage supply lines connect to electrical connections on a side of the integrated circuit die opposite a side of the integrated circuit die coupled to the package substrate.

20. A system comprising:
a processor comprising:
a plurality of metallization layers comprising voltage supply lines and signal lines, each metallization layer on a different respective vertical plane within the processor;
a plurality of logic circuits, each logic circuit comprising non-CMOS logic devices and formed between respective pairs of metallization layers.

21. The system of claim 20, wherein the non-CMOS logic devices include ferroelectric field-effect transistor (FeFET) devices.

22. The system of claim 20, wherein the non-CMOS logic devices include spintronic logic devices.

23. The system of claim 20, wherein each set of logic circuits is formed on a different vertical plane within the processor.

24. The system of claim 20, wherein the voltage supply lines comprise a first set of voltage supply lines to carry a first voltage and a second set of voltage supply lines to carry a second voltage, wherein the first set of voltage supply lines and second set of voltage supply lines are routed in different metallization layers.

25. The system of claim 20, wherein the plurality of logic circuits comprise:
a first logic circuit formed between a first metallization layer of the processor and a second metallization layer of the processor, the first logic circuit comprising non-CMOS logic devices; and
a second logic circuit formed between the second metallization layer and a third metallization layer of the processor, the second logic circuit comprising non-CMOS logic devices.
